(19) United States
(12) Patent Application Publication
(10) Pub. No.: US 2008/0296554 A1
(43) Pub. Date: Dec. 4, 2008

(54) PHASE CHANGE MEMORY DEVICES AND FABRICATION METHODS THEREOF

(75) Inventor: Chien-Min Lee, Kaohsiung City (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARACH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/965,557

(22) Filed: Dec. 27, 2007

(30) Foreign Application Priority Data
May 31, 2007 (TW) TW96119447

(51) Int. Cl. H01L 45/00

(52) U.S. Cl. 257/4; 438/54; 257/E45.002

(57) ABSTRACT

Phase change memory devices and fabrication methods thereof. A phase change memory device includes an array of phase change memory cells. Each phase change memory cell includes a selecting transistor disposed on a substrate. An upright electrode structure is electrically connected to the selecting transistor. An upright phase change memory layer is stacked on the upright electrode structure with a contact area therebetween, wherein the contact area serves as the location where phase transition takes place.

### BACKGROUND OF THE INVENTION

1. Field of the Invention

The invention relates to memory devices and fabrication methods, and in particular to phase change memory cells, phase change memory arrays and fabrication methods thereof.

2. Description of the Related Art

Phase change memory devices are non-volatile, highly readable, highly programmable, and low driving voltage/current devices, and normally applied in non-volatile memory devices. In order to meet high density integration and low current requirements, conventional design rules for phase change memory device is to reduce the contact area between the memory cell and the heating electrode, thus reducing operation currents and minimizing dimensions of transistors to achieve high density and high volume memory devices. However, the electric current provided by the current controlling element such as MOS transistor is limited.

Conventional phase change materials in a phase change memory device have at least two solid phases, a crystalline state and an amorphous state. Transformation between these two phases can be achieved by heating the phase change materials. Different electrical pulses can be selectively input to the phase change materials. The phase change materials can exhibit different electrical characteristics depending on their state. For example, a crystalline phase change material with periodic atomic arrangement can exhibit low electrical resistance, while an amorphous phase change material with random atomic arrangement can exhibit high electrical resistance. The difference in electrical resistances between the crystalline state and the amorphous state can be as high as four orders (10⁴). Such phase change materials may transform between numerous electrically detectable conditions of varying resistances within a nanosecond time scale with the input of a pico joules of energy. Among various phase change materials, alloys containing Ge, Sb, and Te are widely applied to modern phase change memory devices.

Since phase transformation between different states of the phase change material is reversible, memory status can be distinguished by telling whether a memory bit is in a low resistance state (crystalline state) or in a high resistance state (amorphous state). More specifically, by deciding among different resistances of a crystalline state or an amorphous state, a digital memory status “0” or “1” can be read or write on a phase change memory cell.

As a key feature of the conventional phase change memory array, each memory cell is configured as one transistor corresponding to a phase change memory layer also referred as a 1T-1R structure. U.S. Pat. Nos. 6,429,064, 6,605,821, and 6,707,087, the entireties of which are hereby incorporated by reference disclose phase change memory structures. By reducing the thickness of the contact electrode, dimensions of the phase change memory devices can be reduced. Specifically, the desirable programming current of the phase change memory is determined by contact area between the phase change memory layer and the electrode. The desirable programming current of the phase change memory is reduced along with the reduction of the contact area between the phase change memory layer and the electrode. Lower programming current of phase change memory device contributes to smaller transistor dimension. Therefore, higher memory density can thus be achieved.

FIG. 1 is a plan view of a conventional phase change memory (PCM) device employing a sidewall electrode. Referring to FIG. 1, a silicon substrate 10 includes an array of transistors (not shown) connected by conductive lines 20 along a first direction. An electrode structure 32 is physically connected to each transistor. The electrode structure 32 is a square metal wall structure surrounding an insulator 34. A phase change memory layer 40 is disposed on the electrode structure 32 and the insulator 34 at a corner of the square metal wall structure to reduce the contact area between the phase change memory layer 40 and the electrode structure 32. Reducing the contact area means desirable programming current of the phase change memory can also be reduced.

As shown in FIG. 1, however, the phase change memory layer 40 is a planar block in which contact area with the electrode structure 32 is space consuming and still needs to be further reduced as the phase change memory cell density increases. Besides, the contact area fluctuates easily due to the alignment offset of the phase change memory layer 40 to the square metal wall structure 32.

FIGS. 2A-2C are schematic views showing another conventional phase change memory (PCM) device employing a sidewall electrode, wherein FIG. 2A and FIG. 2B are cross sections respectively taken along X direction and Y direction, and FIG. 2C is a planar view of this conventional PCM device. Referring to FIGS. 2A and 2B, a metal plug 55 is disposed in a lower portion of a dielectric layer 50. The other end of the metal plug 55 connects to a transistor device (not shown). An electrode structure 60 is disposed at an upper portion the dielectric layer 50, and electrically connects to the metal plug 55. The electrode structure 60 is a rectangular metal wall structure surrounding an insulator 65. A dielectric layer 72 is disposed on the dielectric layer 50 with stripe openings exposing part of the electrode structure 60. A phase change memory layer 74 is disposed on the dielectric layer 72 filling the stripe openings such that the contact area between the phase change memory layer 74 and the electrode structure 60 is restrained within the stripe openings. The contact area is thus reduced. Metal conductive lines 76 are disposed on the phase change memory layer 74 to serve as bit lines of the PCM devices. A passivation layer 80 is disposed on the metal conductive lines 76 to protect the PCM devices.

However, it is more beneficial to further reduce contact area between the PCM layer and the electrode in order to meet PCM integration requirement. Moreover, conventional PCM devices are constructed with one transistor corresponding to one PCM element (a.k.a. 1T-1R structures). Conventional 1T-1R structures are space-consuming resulting in inefficient arrangement of the PCM array and limitation of PCM integration.

### BRIEF SUMMARY OF THE INVENTION

A detailed description is given in the following embodiments with reference to the accompanying drawings.

An embodiment of the invention provides a phase change memory device, comprising: a current controlling element disposed on a substrate; an upright electrode structure electrically connected to the current controlling element; and a first upright phase change memory layer stacked on the upright electrode structure with a first contact spot therebetween, wherein the first contact spot is served as a phase transition location of a first phase change memory cell.

Another embodiment of the invention further provides a method for fabricating a phase change memory device, comprising: providing a substrate with a current controlling element thereon; forming an upright electrode structure on the substrate electrically connected to the current controlling element; and forming a first upright phase change memory layer on the upright electrode structure serving as a phase change memory cell.

### BRIEF DESCRIPTION OF THE DRAWINGS

The invention can be more fully understood by reading the subsequent detailed description and examples with references made to the accompanying drawings, wherein:

FIG. 1 is a plan view of a conventional phase change memory (PCM) device employing a sidewall electrode;

FIGS. 2A-2C are schematic views showing another conventional phase change memory (PCM) device employing a sidewall electrode, wherein FIG. 2A and FIG. 2B are cross sections respectively taken along X direction and Y direction, and FIG. 2C is a planar view of the conventional PCM device;

FIG. 3 is a schematic view of a PCM cell according to an exemplary embodiment of the invention;

FIG. 4 is a plan view of an exemplary embodiment of a PCM array of the invention;

FIG. 5A is a plan view of an exemplary embodiment of a substrate with an array of MOSFETs thereon;

FIG. 5B is a cross section of an exemplary embodiment of a substrate with an array of MOSFETs thereon;

FIG. 6A is a plan view of another exemplary embodiment of a substrate with an array of BJTs thereon;

FIG. 6B is a cross section of another exemplary embodiment of a substrate with an array of BJTs thereon;

FIGS. 7A-9C are schematic views illustrating each fabrication step of an upright electrode structure on the substrate;

FIGS. 10A-12B are schematic views illustrating each fabrication step of forming an upright phase change memory layer on the upright electrode structure;

FIGS. 13A-14B are schematic views illustrating each fabrication step of forming bit lines connecting the upright PCM layer;

FIGS. 15A-17C are schematic views illustrating each fabrication step of forming an upright phase change memory layer on the upright electrode structure according to the second embodiment of the invention;

FIGS. 18A-19B are schematic views illustrating each fabrication step of forming bit lines connecting the upright PCM layer according to the second embodiment of the invention;

FIG. 20 is a plan view of a configuration of the PCM array according to an embodiment of the invention;

FIG. 21 is a plan view of another configuration of the PCM array according to another embodiment of the invention; and

FIG. 22 is a plan view of another configuration of the PCM array according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims. The term “phase change memory device” of the embodiments of the invention is to be understood as a final product of a memory device including driving integrated circuits. The term “phase change memory array” is to be understood as a periodic arranged group of phase change memory elements without driving integrated circuits. The terms “phase change memory element” and “phase change memory cell” are to be understood as a combinations of a heating electrode and a phase change memory layer, such as 1T-2R structure consisting of one transistor corresponding to two memory cells.

In order to increase integration of the PCM element or the PCM cell, embodiments of the invention provide novel designs of PCM cells and PCM arrays to simultaneously reduce contact area and unit memory cell area. More specifically, by introducing upright heating electrodes and upright phase change memory layers, minimum contact area can thus be achieved and operation currents can thus be further reduced. Meanwhile, by introducing 1T-2R structures, unit cell areas can be shrunken without changing design rules, thereby multiplying PCM density.

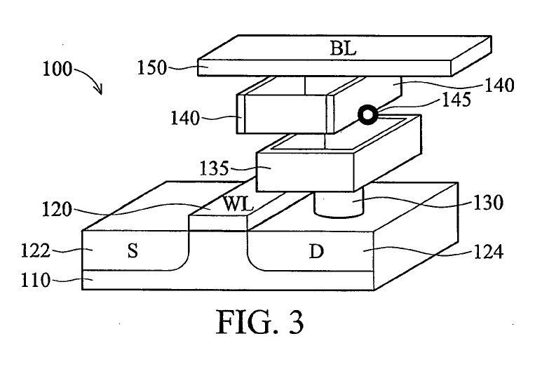

FIG. 3 is a schematic view of a PCM cell according to an exemplary embodiment of the invention. Referring to FIG. 3, a PCM cell 100 comprises an electrical current controlling element disposed on a substrate 110. The electrical current controlling element can be a transistor such as a MOS transistor with a gate electrode 120, a source 122, and a drain 124. The gate electrode 120 of the MOS transistor is connected to gate electrodes of other MOS transistors by a word line (WL) along a first direction. An upright electrode structure 135 and the electrical current controlling element are electrically connected through a conductive plug 130. An upright PCM layer 140 is stacked on the upright electrode structure 135 with a contact spot 145 therebetween, wherein the contact spot 145 serves as a phase transition location of a first phase change memory cell. A bit line (BL) 150 connects each upright phase change memory layer 140 in series along a second direction, wherein the first and the second directions are substantially crossed at right angles.

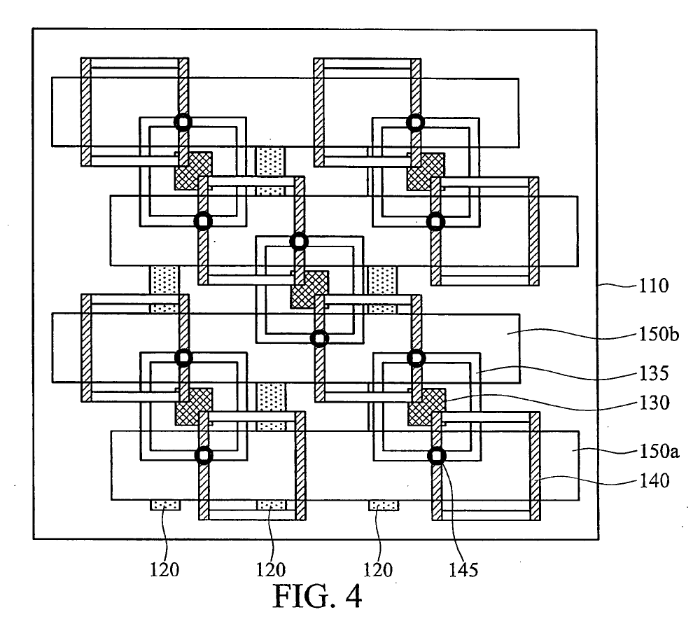

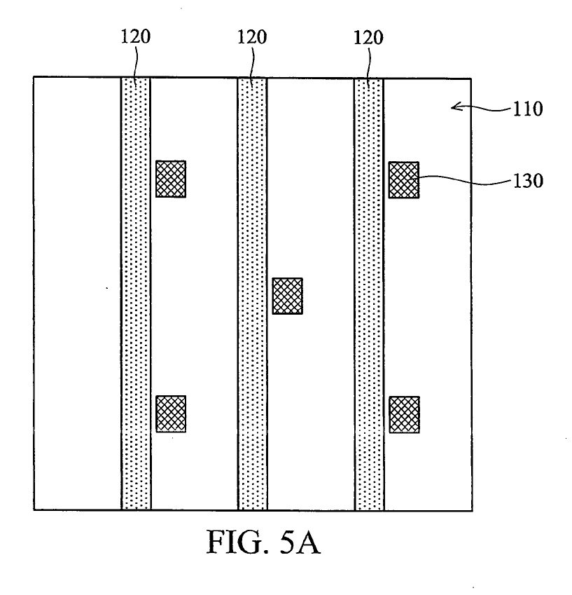

FIG. 4 is a plan view of an exemplary embodiment of a PCM array of the invention. In FIG. 4, an array of PCM cells 100 of FIG. 3 connects the corresponding electrical current controlling elements on the substrate 110 through conductive plugs 130. A plurality of word lines connects each electrical current controlling element in series along the first direction. A plurality of first bit lines 150a connects a set of upright phase change memory layers 140 in series along a second direction, and a plurality of second bit lines 150b connects another set of second upright phase change memory layers 140 in series along the second direction, wherein the first and the second directions are substantially crossed at right angles.

Referring to FIG. 4, an embodiment of a PCM array of the invention comprises an array of transistor elements serving as current controlling elements. Each transistor corresponds to a conductive plug 130. The transistor element array can comprise a first set of transistor sub-arrays and a second set of transistor sub-arrays. The first set transistor sub-arrays is located at (m, n) lattice sites, and the second set transistor sub-arrays is located at (m+½, n+½) lattice sites, where m and n are integrals. More specifically, the first set of transistor sub-arrays and the second set of transistor sub-arrays are configured as a (½, ½) translation symmetry.

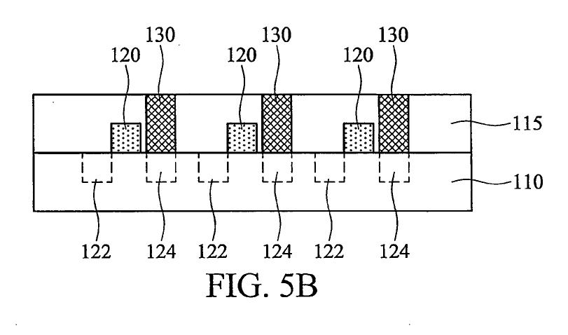

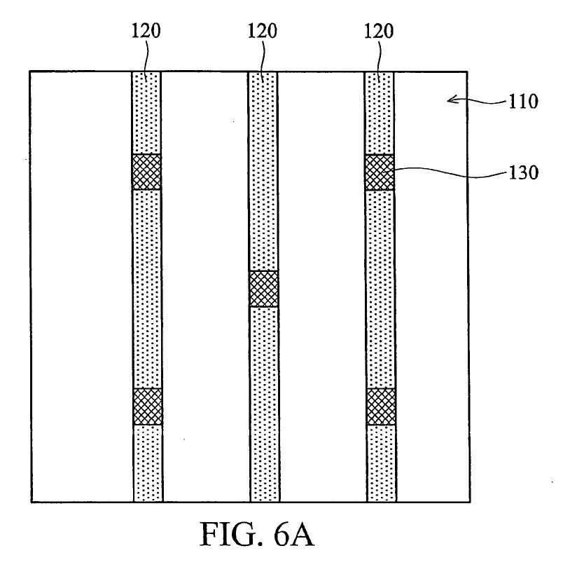

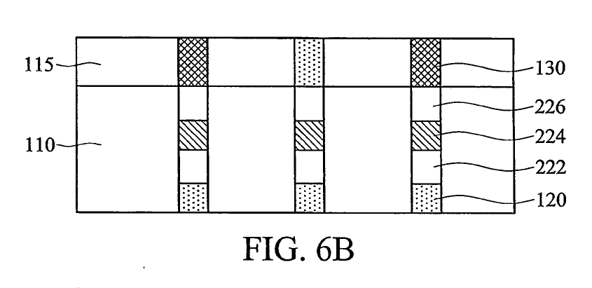

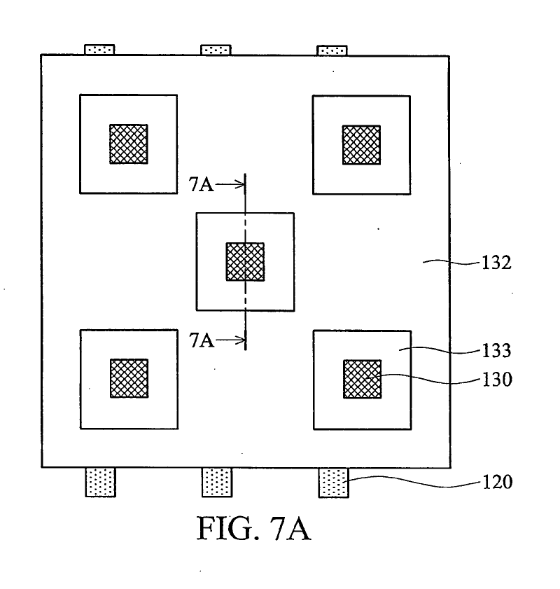

FIGS. 5A-14B are schematic views illustrating each fabrication step of a first embodiment of the PCM array of the invention. A substrate 110, including any type of semiconductor substrate, is provided with an array of current controlling elements thereon. The control terminal (e.g., a gate electrode) of each current controlling element is connected in series by a plurality of parallel word lines, and an output terminal of each current controlling element is connected to a conductive plug 130. The current controlling element can comprise a transistor such as a metal-oxide-metal field effect transistor (MOSFET), a PN junction diode, or bipolar junction transistor (BJT). FIG. 5A is a plan view of an exemplary embodiment of a substrate 110 with an array of MOSFETs thereon. A cross section of the MOSFET array substrate 110 is shown in FIG. 5B. Each MOSFET includes a gate 120, a source 122, and a drain 124. FIG. 6A is a plan view of another exemplary embodiment of a substrate 110 with an array of BJTs thereon. A cross section of the BJT array substrate 110 is shown in FIG. 6B. The BJT can comprise a pnp transistor or an npn transistor, both of which consist of three electrodes indicted as references 222, 224 and 226.

Referring to FIG. 6B, a first dielectric layer 115 is formed on the substrate 110. Conductive plugs 130 are formed in the first dielectric layer 115.

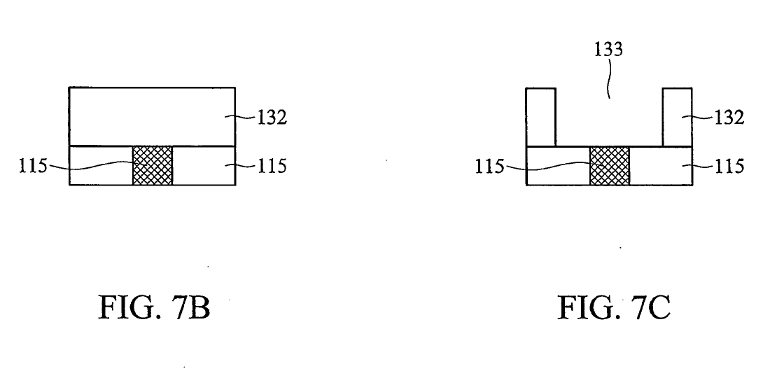

FIGS. 7A-9C are schematic views illustrating each fabrication step of an upright electrode structure on the substrate 110. Referring to FIG. 7A, a second dielectric layer 132 is formed on the first dielectric layer 115, the cross section of which taken along line 7A-7A is shown in FIG. 7B. A lithographic etching process is performed patterning the second dielectric layer 132 to create pluralities of openings 133 exposing the respective conductive plug 130, the cross section of which taken along line 7A-7A is shown in FIG. 7C. Openings 133 can be of any shape such as a square opening.

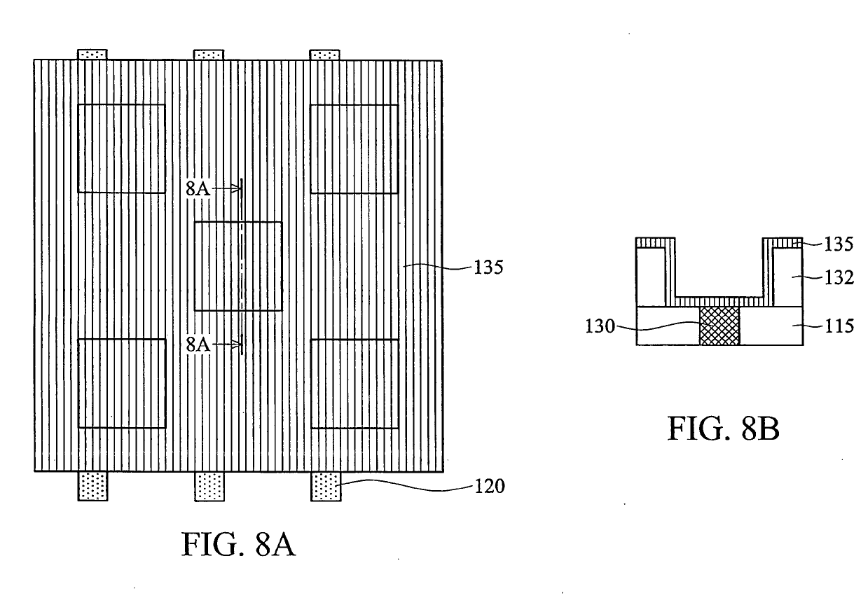

Referring to FIG. 8A, a first conductive layer 135 is conformably deposited on the second dielectric layer 132 and opening 133, the cross section of which taken along line 8A-8A is shown in FIG. 8B. The first conductive layer 135 can be deposited by metallic thin film deposition techniques such as sputtering, physical vapor deposition (PVD), or chemical vapor deposition (CVD). The first conductive layer 135 can comprise a high Tm (melting point) conductive material comprising transition metals, rare earth metals, or alloys thereof, nitrides thereof, carbides thereof, or nitro-carbides thereof.

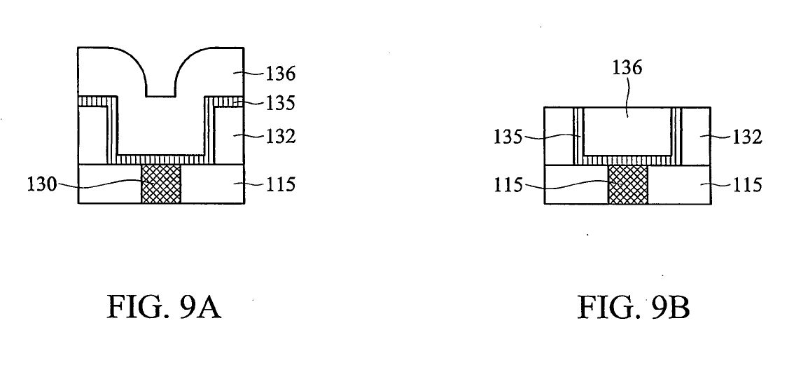

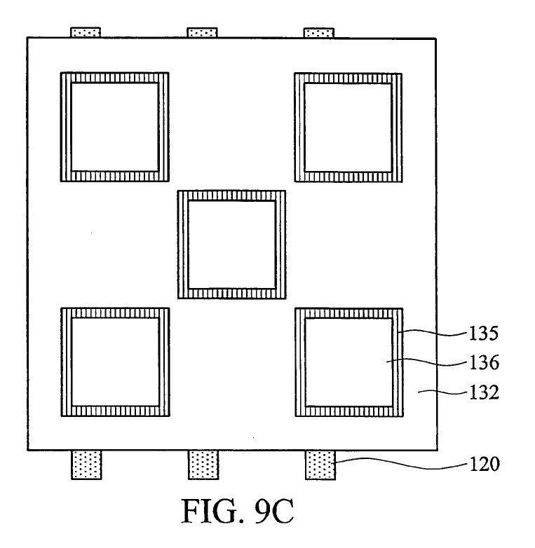

Referring to 9A, a third dielectric layer 136 is formed on the first conductive layer 135 filling the opening 133. Planarization, such as chemical mechanical planarization (CMP) is subsequently performed to remove the third dielectric 136 and the first conductive layer 135 until exposing the surface of the second dielectric layer 132, as shown in FIG. 9B. A square conductive wall structure 135 is thus created to serve as an upright electrode structure of the PCM element, the plan view of which is shown in FIG. 9C.

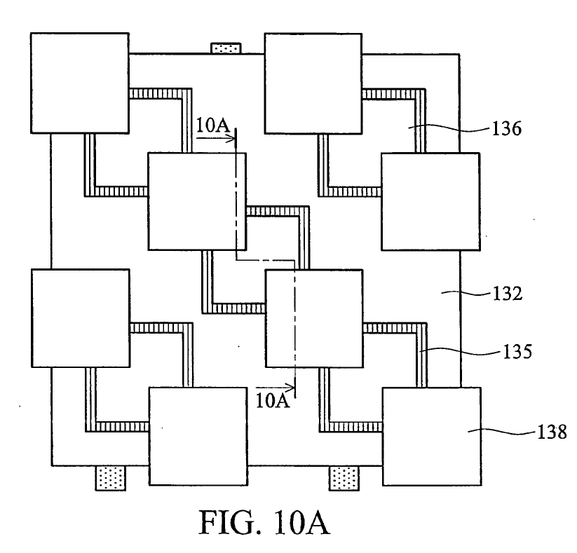

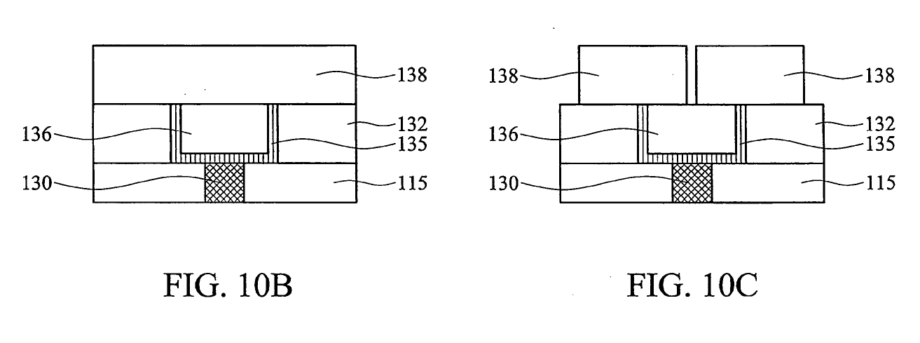

FIGS. 10A-12B are schematic views illustrating each fabrication step of forming an upright phase change memory layer on the upright electrode structure. Referring to FIG. 10A, a fourth dielectric layer 138 is formed on the third dielectric layer 132, the cross section of which taken along line 10A-10A is shown in FIG. 10B. The fourth dielectric layer 138 is then patterned to create an island structure. The island structure can be any shape such as a square island structure, but is not limited thereto, the cross section of which taken along line 10A-10A is shown in FIG. 10C. The island structure is formed on the square conductive wall structure 135 and disposed at a corner of the square conductive wall structure 135.

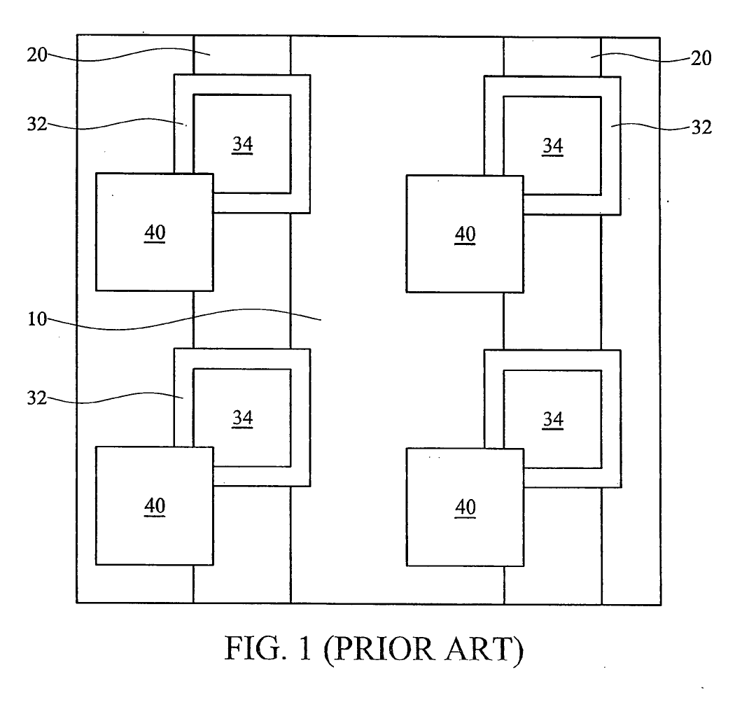

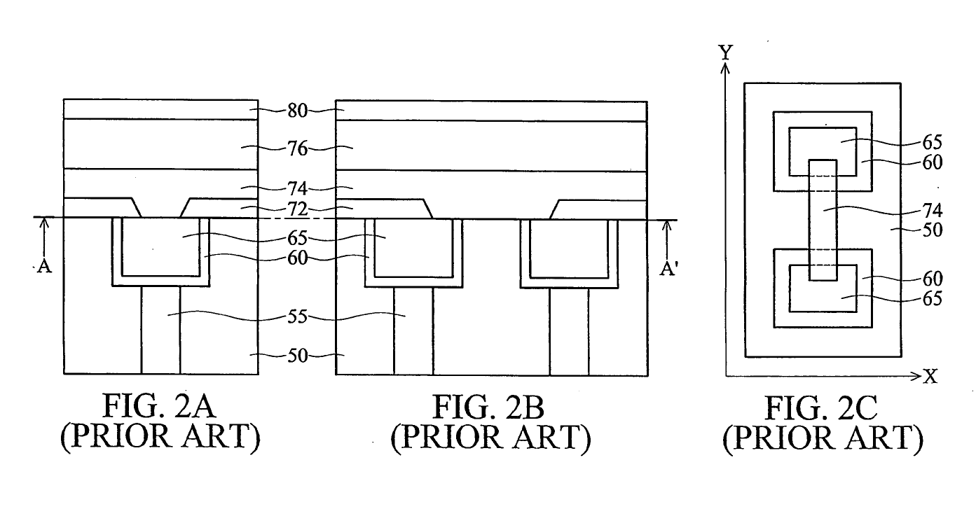

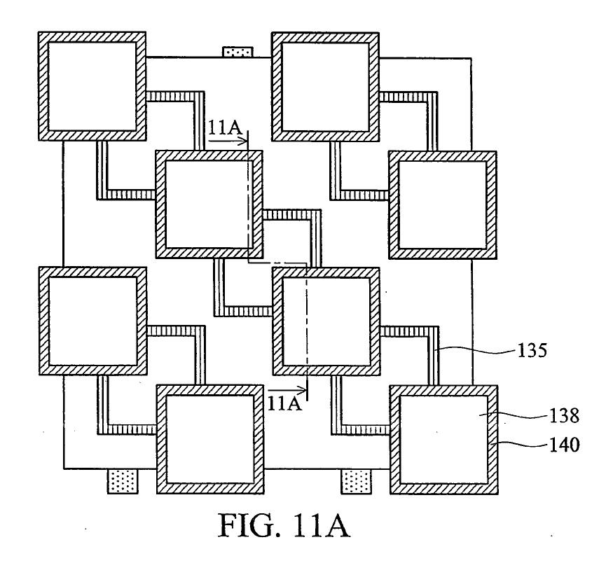

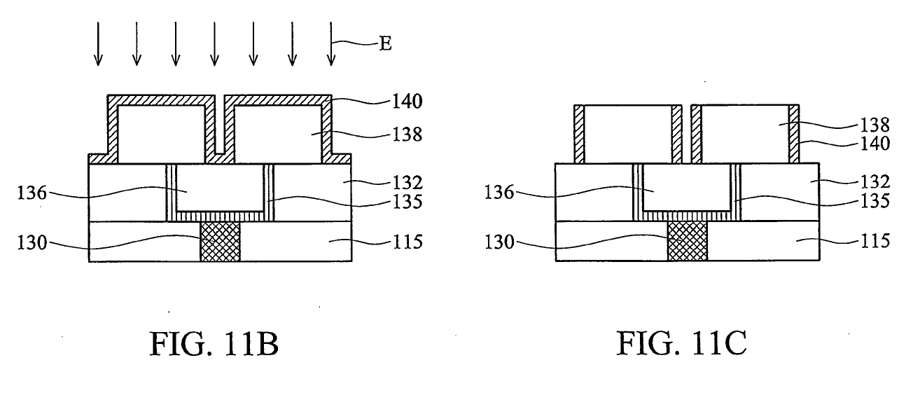

Referring to FIG. 11A, a second conductive layer 140 is conformably formed on the fourth dielectric layer 138 and the third dielectric layer 136, the cross section of which taken along line 11A-11A is shown in FIG. 11B. An anisotropic etching back process E is performed removing part of the second conductive layer 140 to create a conductive spacer structure on the sidewalls of the square island structure 138, the cross section of which taken along line 11A-11A is shown in FIG. 1 IC. The second conductive layer 140 is made of phase change memory materials by controlling the status of the generated phase thereof for memory. The phase change memory materials comprise group III, group IV, group V, group VI metals, or alloys thereof.

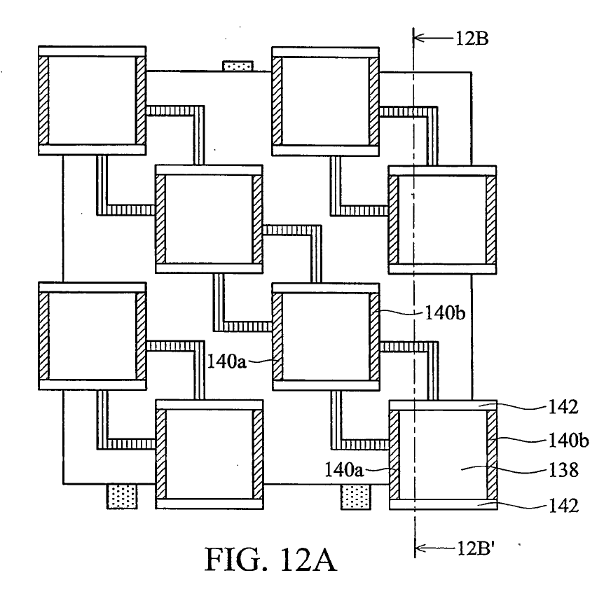

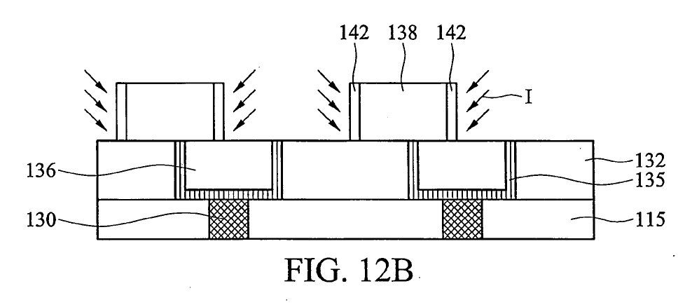

Referring to FIG. 12A, one parallel pair of the spacer walls 142 in a second direction are insulated, and the other parallel pair of the spacer walls 140a, 140b are remained conductive in a first direction to serve as a first upright phase change memory layer 140a and a second upright phase change memory layer 140b respectively. According to another embodiment of the invention, insulation of the parallel pair of spacers 142 can be performed by inclined ion implantation I. Two opposing spacer walls are implanted with oxygen ion or nitrogen ion from two inclined directions for insulation, the cross section of which taken along line 12B-12B′ is shown in FIG. 12B.

The two opposing metal spacer walls 140a and 140b are isolated single metal wall structures serving as an upright PCM layer. The upright PCM layers 140a and 140b stacked on the upright electrode structure 135 with a contact spot therebetween, act as a phase transition location of a first phase change memory cell. According in another embodiment of the invention, the upright electrode structure 135 and the upright PCM layers 140a and 140b are uprightly crossed, wherein the upright electrode structure 135 and the upright PCM layers 140a and 140b are intersected vertically or non-vertically.

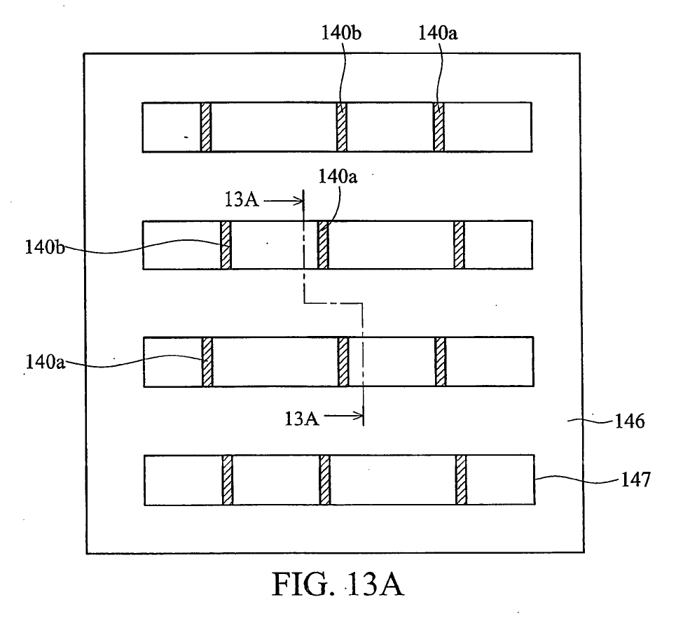

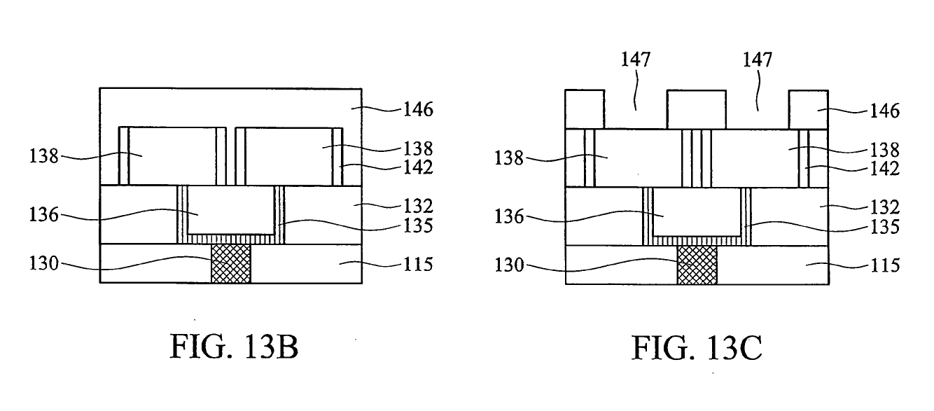

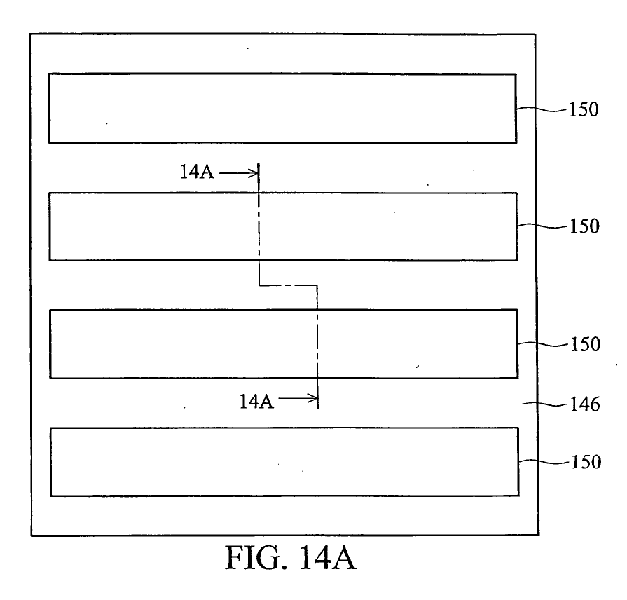

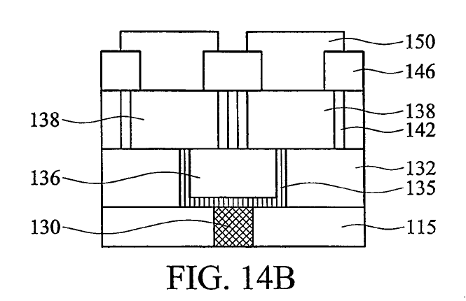

FIGS. 13A-14B are schematic views illustrating each fabrication step of forming bit lines connecting to the upright PCM layer. Referring to FIG. 13A, a fifth dielectric layer 146 is deposited on the fourth dielectric layer 132 and on the upright PCM layers 140a, 140b. The fifth dielectric layer 146 is subsequently planarized, the cross section of which taken along line 13A-13A is shown in FIG. 13B.

Subsequently, a lithographic etching process is performed patterning the fifth dielectric layer 146 to create a plurality of parallel trenches 147 exposing the upright PCM layers 140a and 140b, the cross section of which taken along line 13A-13A is shown in FIG. 13C.

Referring to FIG. 14A, a third conductive layer 150 is deposited on the fifth dielectric layer 146 filling the trenches 147. A lithographic etching process is sequentially performed patterning the third conductive layer 150 into a plurality of conductive lines along the second direction to serve as bit lines of the PCM device, of which the cross section taken along line 14A-14A is shown in FIG. 14B.

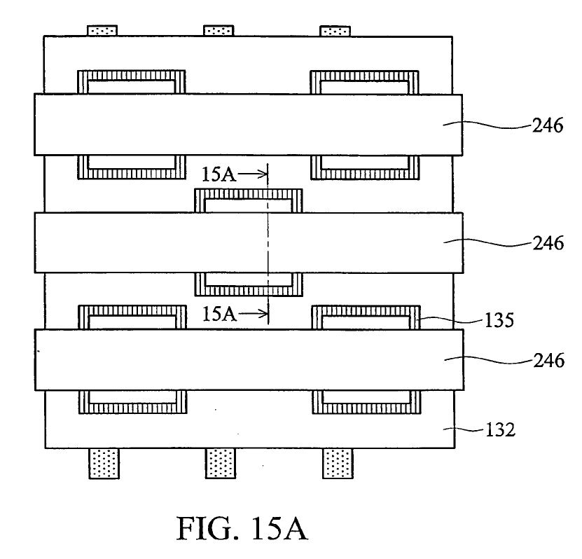

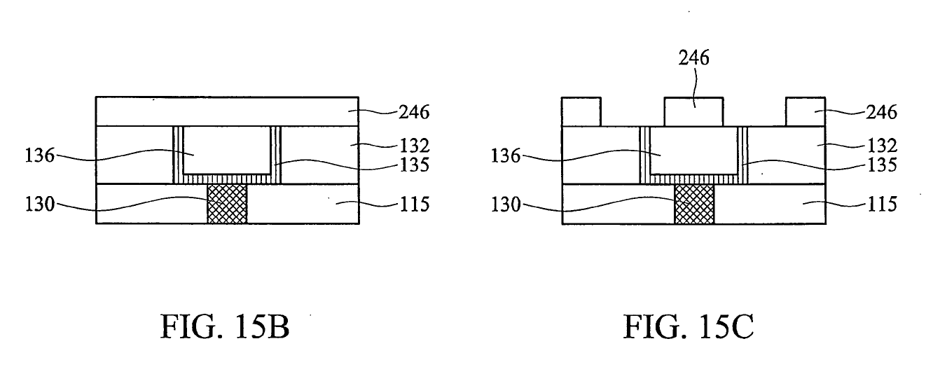

FIGS. 15A-19C are schematic views illustrating each fabrication step of a second embodiment of the PCM array of the invention. The fabrication steps of the second embodiment of the PCM array are substantially similar to the fabrication steps depicted in FIGS. 5A-9C of the first embodiment and for brevity, detailed description thereby is omitted. However, fabrication steps of the upright PCM layers are different in the second embodiment.

FIGS. 15A-17C are schematic views illustrating each fabrication step of forming an upright phase change memory layer on the upright electrode structure according to the second embodiment of the invention. Referring to FIG. 15A, a fourth dielectric layer 246 is formed on the third dielectric layer 132, the cross section of which taken along line 15A-15A is shown in FIG. 15B. The fourth dielectric layer 246 is then patterned along the second direction to create a plurality of stripe island structures 246. Each stripe island structure crosses over each upright electrode structure 135, the cross section of which taken along line 15A-15A is shown in FIG. 15C.

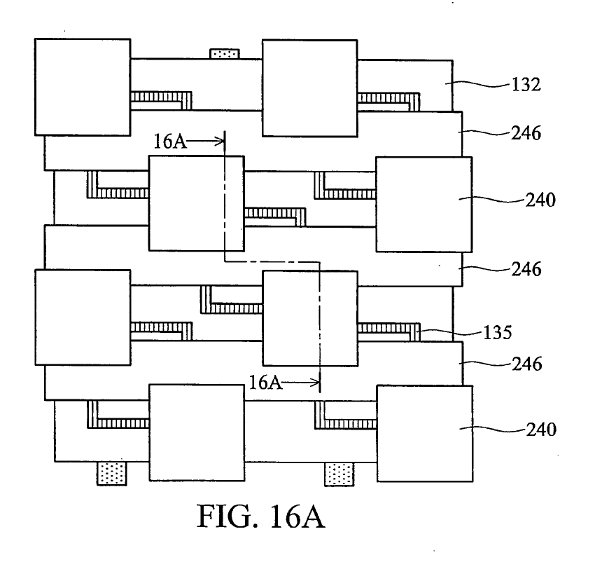

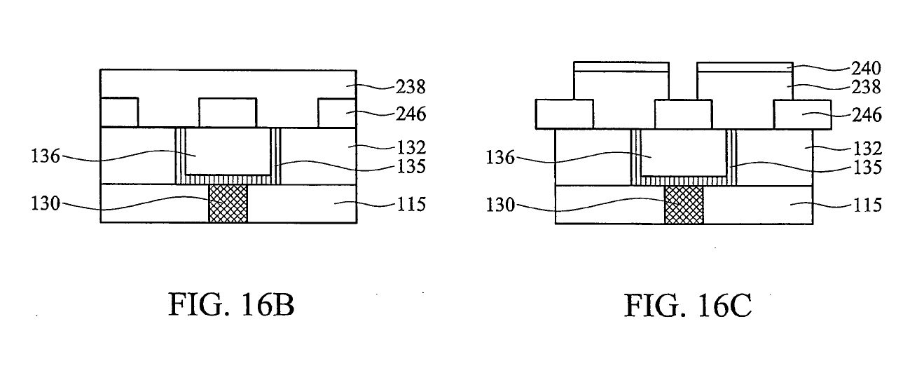

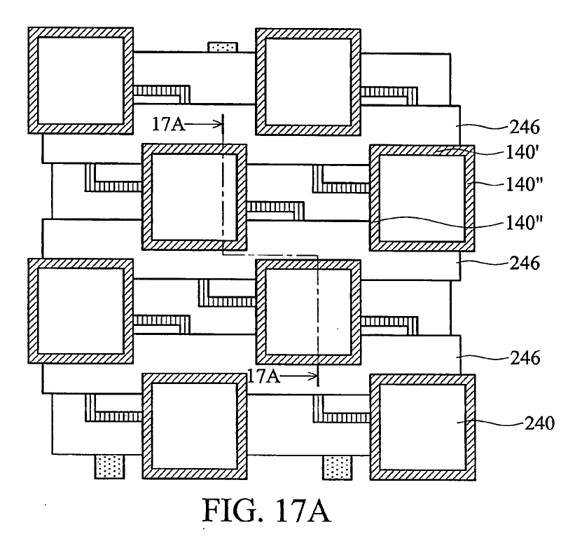

Referring to FIG. 16A, a fifth dielectric layer 238 is formed on the third dielectric layer 132 and the fourth dielectric layer (stripe island structure) 246. The fifth dielectric layer 238 exhibits relatively higher etching rate to the fourth dielectric layer 246. The fifth dielectric layer 238 is then planarized, the cross section of which taken along line 16A-16A is shown in FIG. 16B. Subsequently, a clad metal layer 240 is formed on the fifth dielectric layer 238. The clad metal layer 240 and the fifth dielectric layer 238 are sequentially etched patterned into island structures. The island structures can be of any shape such as a square island structure, but is not limited thereto. The island structure is formed at a corner of the square conductive wall structure 135, the cross section of which taken along line 16A-16A is shown in FIG. 16C.

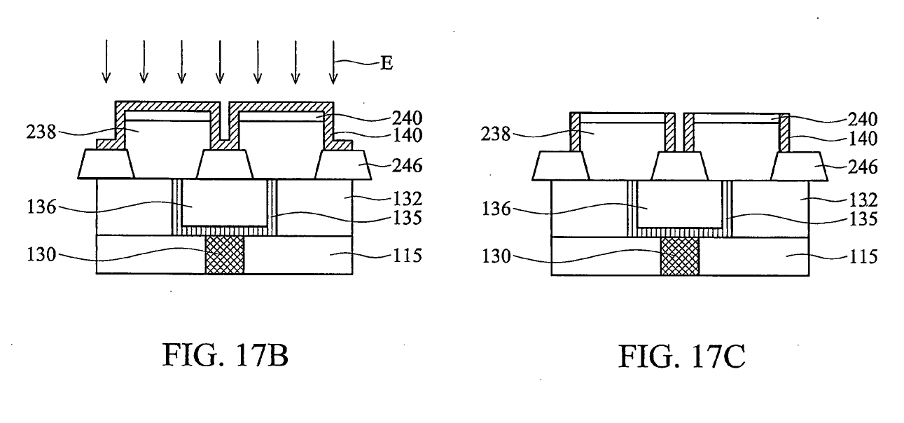

Referring to FIG. 17A, a second conductive layer 140 is conformably formed on the clad metal layer (island structure) 240 and the fourth dielectric layer (stripe island structure) 246, the cross section of which taken along line 17A-17A is shown in FIG. 17B. An anisotropic etching back process E is subsequently performed removing part of the second metal layer 140 to create a conductive spacer structure on the sidewalls of the square island structure, the cross section of which taken along line 17A-17A is shown in FIG. 17C. The second conductive layer 140 is made of phase change memory materials by controlling the status of the generated phase thereof for memory. The phase change memory materials comprise group III, group IV, group V, group VI metals, or alloys thereof.

Two opposing second conductive spacer walls 140′ parallel to the second direction are insulated from the upright electrode structure with a fourth dielectric layer (stripe island structure) 246, while the other parallel pair of opposing second conductive spacer walls 140″ are remained conductive in the first direction to serve as a first upright phase change memory layer and a second upright phase change memory layer respectively as shown in FIG. 17A.

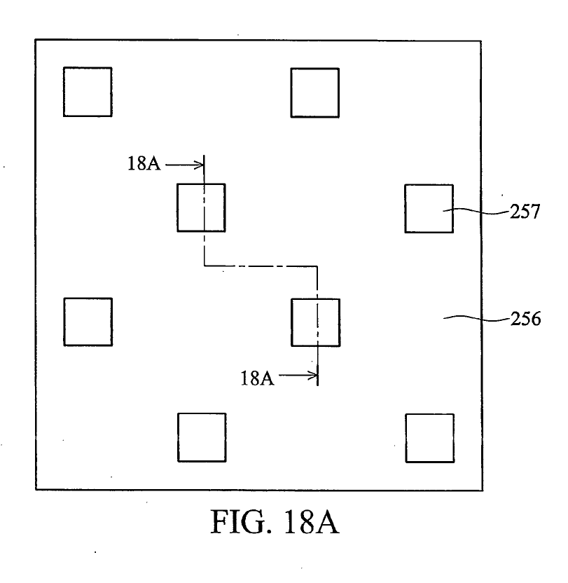

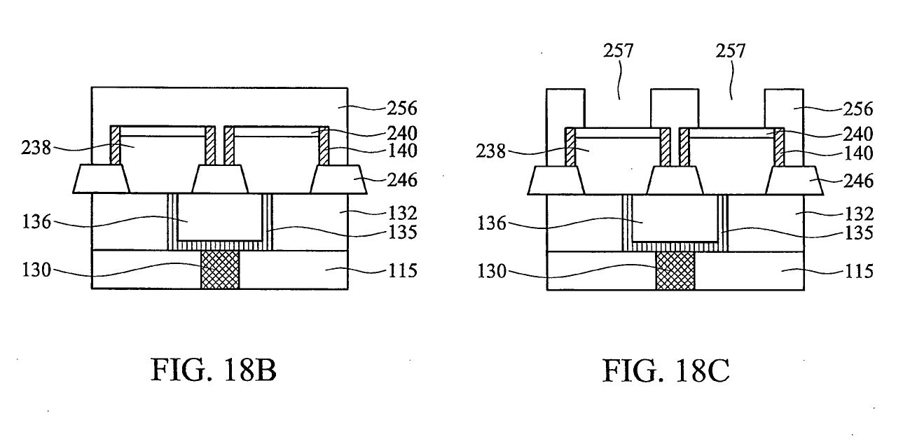

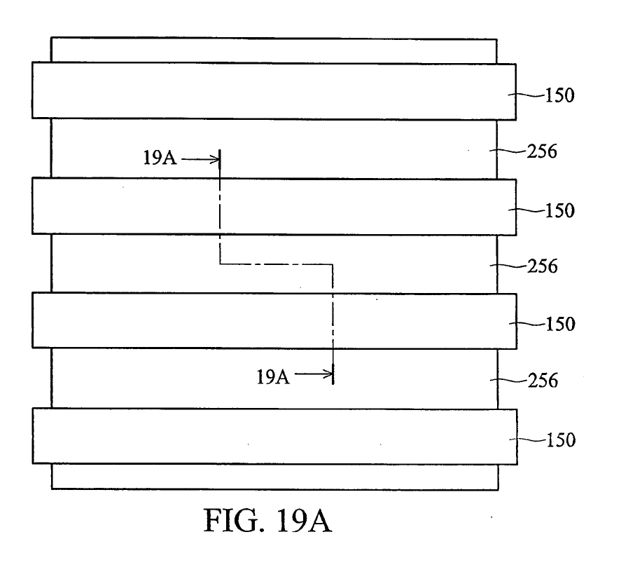

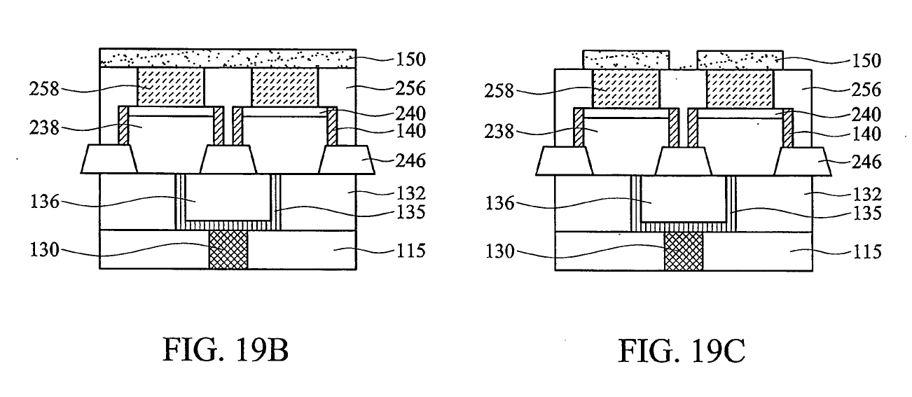

FIGS. 18A-19B are schematic views illustrating each fabrication step of forming bit lines connecting the upright PCM layer according to the second embodiment of the invention. Referring to FIG. 18A, a sixth dielectric layer 256 is deposited on the clad metal layer (island structure) 240 and the fourth dielectric layer (stripe island structure) 246. The sixth dielectric layer 256 is subsequently planarized, the cross section of which taken along line 18A-18A is shown in FIG. 18B.

Subsequently, a lithographic etching process is performed patterning the sixth dielectric layer 256 exposing the clad metal layer 240, the cross section of which taken along line 18A-18A is shown in FIG. 18C.

Referring to FIG. 19A, a third conductive layer 150 is deposited on the sixth dielectric layer 256 filling the contact windows 257 forming contact plugs 258. A lithographic etching process is sequentially performed patterning the third conductive layer 150 into a plurality of conductive lines along the second direction to serve as bit lines of the PCM device, the cross section of which taken along line 19A-19A is shown in FIG. 19C.

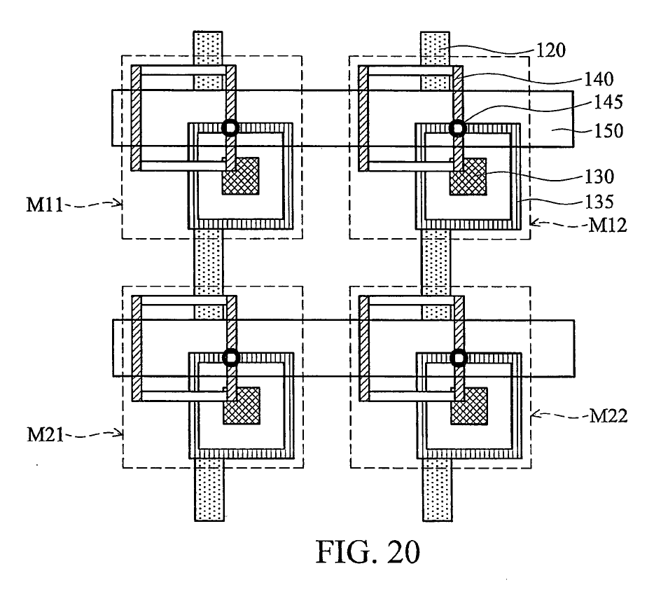

FIG. 20 is a plan view of a configuration of the PCM array according to an embodiment of the invention. In FIG. 20, a PCM array can be a square matrix consisting of four PCM elements M11-M22. Each PCM element comprises one transistor corresponding to one PCM cell (1T-1R structure). The transistor of each PCM element connects the upright electrode structure 135 through a conductive plug 130. An upright phase change memory layer 140 is stacked on the upright electrode structure 135 with a contact spot 145 therebetween to serve as a phase transition location of the phase change memory cell. A word line 120 connects each transistor in series along the first direction, and a bit line 150 connects each upright phase change memory layer 140 in series along a second direction.

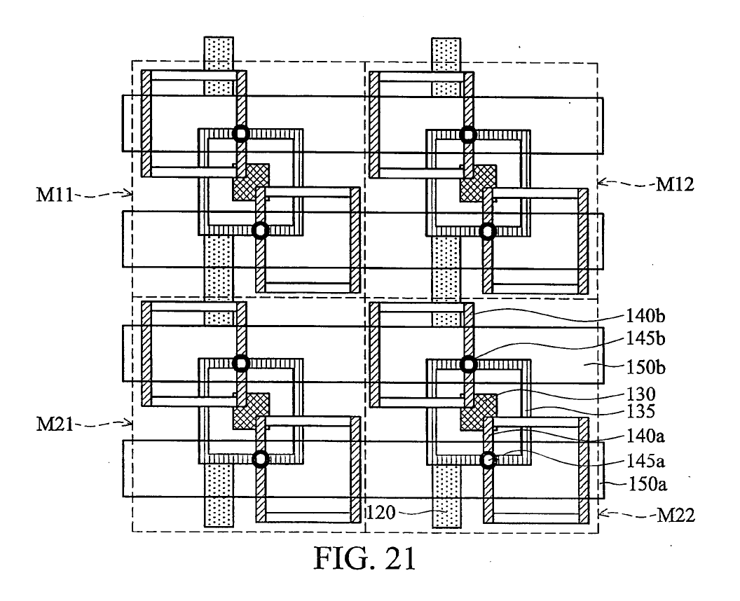

FIG. 21 is a plan view of another configuration of the PCM array according to another embodiment of the invention. In FIG. 21, a PCM array can be a square matrix consisting of four PCM elements M11-M22. Each PCM element comprises one transistor corresponding to two PCM cell (1T-2R structure). The transistor of each PCM element connects to the upright electrode structure 135 through a conductive plug 130. A first upright phase change memory layer 140a is stacked on the upright electrode structure 135 with a contact spot 145a therebetween to serve as a phase transition location of the first phase change memory cell. A second upright phase change memory layer 140b is stacked on the upright electrode structure 135 with a contact spot 145b therebetween to serve as a phase transition location of the second phase change memory cell. A word line 120 connects each transistor in series along the first direction. A first bit line 150a connects each first upright phase change memory layer 140a in series along a second direction, and a second bit line 150b connects each second upright phase change memory layer 140b in series along a second direction.

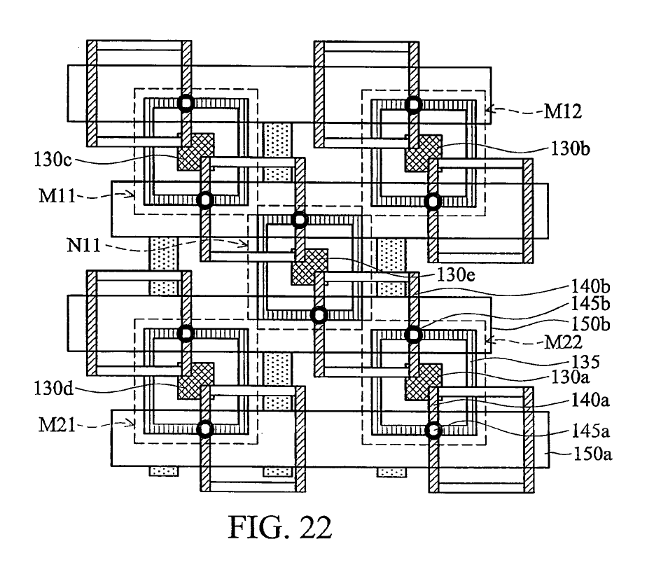

FIG. 22 is a plan view of another configuration of the PCM array according to another embodiment of the invention. In FIG. 22, a PCM array can be a square matrix consisting of four PCM elements M11-M22 and a PCM element N11. Each PCM element comprises one transistor corresponding to two PCM cell (1T-2R structure). The transistor of each PCM element connects to the upright electrode structure 135 through a conductive plug 130. A first upright phase change memory layer 140a is stacked on the upright electrode structure 135 with a contact spot 145a therebetween to serve as a phase transition location of the first phase change memory cell. A second upright phase change memory layer 140b is stacked on the upright electrode structure 135 with a contact spot 145b therebetween to serve as a phase transition location of the second phase change memory cell. A word line 120 connects each transistor in series along the first direction. A first bit line 150a and a second bit line 150b here connect both first upright phase change memory layer 140a and second upright phase change memory layer 140b in series alternately along a second direction.

The PCM array can comprise a first set of transistor sub-arrays (corresponding to locations at conductive plugs 130a-130d) and a second set of transistor sub-arrays (corresponding to a location at conductive plug 130e). The first set of transistor sub-arrays is located at (m, n) lattice sites, and the second set of transistor sub-arrays is located at (m, n) lattice sites, where m and n are integrals. More specifically, the first set of transistor sub-arrays and the second set of transistor sub-arrays are configured as a (½, ½) translation symmetry.

The embodiments of the invention are beneficial in that both the electrode and the PCM layer are upright structures, thus contact area therebetween can be effectively reduced. Furthermore, by using one current controlling element corresponding to two PCM elements (also referred as 1T-2R structures), area of a PCM unit cell is reduced and PCM device integration is improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase change memory device, comprising:
a current controlling element disposed on a substrate;
an upright electrode structure electrically connected to the current controlling element; and
a first upright phase change memory layer stacked on the upright electrode structure with a first contact spot therebetween, wherein the first contact spot serves as a phase transition location of a first phase change memory cell.

2. The phase change memory device as claimed in claim 1, wherein the upright electrode structure is a conductive wall structure.

3. The phase change memory device as claimed in claim 1, wherein the first upright phase change memory layer is a single wall structure.

4. The phase change memory device as claimed in claim 1, wherein the upright electrode structure and the first upright phase change memory layer are uprightly crossed, wherein the upright electrode structure and the first upright phase change memory layer are intersected vertically or non-vertically.

5. The phase change memory device as claimed in claim 2, wherein the upright electrode structure comprises a high Tm (melting point) conductive material comprising transition metals, rare earth metals, or alloys thereof, nitrides thereof, carbides thereof, or nitro-carbides thereof.

6. The phase change memory device as claimed in claim 3, wherein the first upright phase change memory layer comprises phase change memory materials by controlling the status of the generated phase thereof for memory.

7. The phase change memory device as claimed in claim 6, wherein the phase change memory materials comprise group III, group IV, group V, group VI metals, or alloys thereof.

8. The phase change memory device as claimed in claim 1, wherein the current controlling element is a transistor element.

9. The phase change memory device as claimed in claim 1, further comprising a second upright phase change memory layer stacked on the upright electrode structure with a second contact spot therebetween, wherein the second contact spot serves as a phase transition location of a second phase change memory cell.

10. The phase change memory device as claimed in claim 9, wherein the second upright phase change memory layer is a single wall structure.

11. The phase change memory device as claimed in claim 9, wherein the upright electrode structure and the second upright phase change memory layer are uprightly crossed, wherein the upright electrode structure and the second upright phase change memory layer are intersected vertically or non-vertically.

12. The phase change memory device as claimed in claim 10, wherein the second upright phase change memory layer is made of phase change memory materials by controlling the status of the generated phase thereof for memory.

13. The phase change memory device as claimed in claim 12, wherein the phase change memory materials comprise group III, group IV, group V, group VI metals, or alloys thereof.

14. The phase change memory device as claimed in claim 9, wherein the first and the second upright phase change memory layers are separately connected to two different conductive lines, wherein each conductive line corresponds to a bit line of the phase change memory device.

15. The phase change memory device as claimed in claim 1, further comprising:
a plurality of the first phase change memory cells arranged in an array corresponding to a plurality of current controlling elements on the substrate;
a plurality of word lines connecting each current controlling element in series along a first direction; and
a plurality of bit lines connecting each first upright phase change memory layer in series along a second direction,
wherein the first and the second directions are substantially crossed at right angles.

16. The phase change memory device as claimed in claim 9, further comprising:
a plurality of the first phase change memory cells and a plurality of the second phase change memory cells arranged in an array corresponding to a plurality of current controlling elements on the substrate;
a plurality of word lines connecting each current controlling element in series along a first direction;
a plurality of first bit lines connecting each first upright phase change memory layer in series along a second direction; and
a plurality of second bit lines connecting each second upright phase change memory layer in series along the second direction,
wherein the first and the second directions are substantially crossed at right angles.

17. The phase change memory device as claimed in claim 16, wherein the plurality of current controlling elements are arranged in an array comprising a first set of transistor sub-arrays and a second set of transistor sub-arrays.

18. The phase change memory device as claimed in claim 17, wherein the first set of transistor sub-arrays and the second set of transistor sub-arrays are configured as a (½, ½) translation symmetry.

19. A method for fabricating a phase change memory device, comprising:
providing a substrate with a current controlling element thereon;
forming an upright electrode structure on the substrate electrically connected to the current controlling element; and
forming a first upright phase change memory layer and a second phase change layer on the upright electrode structure.

20. The method as claimed in claim 19, wherein the current controlling element is a transistor element.

21. The method as claimed in claim 19, wherein the substrate comprises a first dielectric layer and a conductive plug in the first dielectric layer, wherein the conductive plug electrically connects to the current controlling element and the upright electrode structure.

22. The method as claimed in claim 19, wherein formation of the upright electrode structure comprises:
forming a second dielectric layer on the first dielectric layer;
patterning the second dielectric layer to create a square opening exposing the conductive plug;
conformably depositing a first conductive layer on the second dielectric layer and the square opening;
depositing a third dielectric layer on the first conductive layer filling in the square opening: and
planarizing the third dielectric layer and the first conductive layer until exposing the second dielectric layer thereby creating a conductive wall structure.

23. The method as claimed in claim 22, wherein the first conductive layer comprises a high Tm (melting point) conductive material comprising transition metals, rare earth metals, or alloys thereof, nitrides thereof, carbides thereof, or nitro-carbides thereof.

24. The method as claimed in claim 19, wherein formation of a first upright phase change memory layer and a second upright phase change memory layer comprises:
forming a fourth dielectric layer on the third dielectric layer;
patterning the fourth dielectric layer to create a square island structure;
conformably depositing a second conductive layer on the fourth dielectric layer and the third dielectric layer;
anisotropically etching the second conductive layer to create spacers on the square island structure; and
insulating one parallel pair of the spacer walls in a second direction and not insulating the other parallel pair of the spacer walls in a first direction to serve as a first upright phase change layer and a second upright phase change memory layer.

25. The method as claimed in claim 24, wherein the first upright phase change layer and the second upright phase change memory layer are made of phase change memory materials by controlling the status of the generated phase thereof for memory.

26. The method as claimed in claim 25, wherein the phase change memory materials comprise group III, group IV, group V, group VI metals, or alloys thereof.

27. The method as claimed in claim 24, wherein insulating one parallel pair of the spacer walls in a second direction comprises ion-implanting oxygen or nitrogen ions into the parallel pair of spacer walls in the second direction.

28. The method as claimed in claim 19, further comprising forming a first bit line connecting the first upright phase change memory layer along the second direction, and forming a second bit line connecting to the second upright phase change memory layer.

29. The method as claimed in claim 28, wherein formation of the first and the second bit lines comprises:
depositing a fifth dielectric layer on the fourth dielectric layer and planarizing the fifth dielectric layer;
etching the fifth dielectric layer to create a first trench and a second trench along the second direction, thereby exposing the first and the second upright phase change memory layers;
depositing a third metal layer on the fifth dielectric layer and filling the first trench and the second trench; and
etching the third conductive layer, thereby creating the first and the second bit lines.

30. The method as claimed in claim 22, wherein formation of a first upright phase change memory layer and a second upright phase change memory layer comprises:
forming a fourth dielectric layer on the third dielectric layer;
patterning the fourth dielectric layer to create a stripe island structure along the second direction;
forming a fifth dielectric layer on the third and the fourth dielectric layers and planarizing the fifth dielectric layer;
forming a clad metal layer on the fifth dielectric layer;
patterning the clad metal layer and the fifth dielectric layer to create a square island structure;
conformably depositing a second conductive layer on the clad metal layer and the fourth dielectric layer; and
anisotropically etching the second conductive layer to create spacers on the square island structure;
wherein the pair of spacer walls of the second conductive layer in the second direction are insulated from the upright electrode structure by the stripe island structure, and the pair of spacer walls of the second conductive layer in the first direction serve as a first upright phase change memory layer and a second upright phase change memory layer.

31. The method as claimed in claim 30, wherein the first upright phase change memory layer and the second upright phase change memory layer are made of phase change memory materials by controlling the status of the generated phase thereof for memory.

32. The method as claimed in claim 30, wherein the phase change memory materials comprise group III, group IV, group V, group VI metals, or alloys thereof.

33. The method as claimed in claim 30, further comprising forming a first bit line connecting to the first upright phase change memory layer along the second direction, and forming a second bit line connecting to the second upright phase change memory layer.

34. The method as claimed in claim 33, wherein formation of the first and the second bit lines comprises:
depositing a sixth dielectric layer on the fifth dielectric layer and planarizing the sixth dielectric layer;
etching the sixth dielectric layer to create a plurality of contact windows exposing the clad metal layer;
depositing a third conductive layer on the sixth dielectric layer and filling the plurality of contact windows, thereby creating a plurality of contact plugs; and
etching the third conductive layer along the second direction to create a plurality of bit lines.

35. A method for fabricating a phase change memory device, comprising:
providing a substrate with a plurality of current controlling elements arranged in an array and a plurality of word lines connecting to the current controlling elements in series;
forming an upright electrode structure corresponding to each current controlling element on the substrate and electrically connecting to the current controlling element; and
forming a first upright phase change memory layer on the upright electrode structure with a first contact spot therebetween, wherein the first contact spot serves as a first phase change memory cell; and
forming a second upright phase change memory layer on the upright electrode structure with a second contact spot therebetween, wherein the second contact spot serves as a second phase change memory cell, wherein the first phase change memory cell is in parallel with the second phase change memory cell.

36. The method as claimed in claim 35, wherein the plurality of current controlling elements are arranged in an array comprising a first set of transistor sub-arrays and a second set of transistor sub-arrays.

37. The method as claimed in claim 36, wherein the first set of transistor sub-arrays and the second set of transistor sub-arrays are configured as a (½, ½) translation symmetry.
